(19) United States
(12) Patent Application Publication
(10) Pub. No.: US 2024/0082885 A1
(43) Pub. Date: Mar. 14, 2024

(54) SUBSTRATE CLEANING DEVICE AND METHOD OF CLEANING SUBSTRATE

(71) Applicant: EBARA CORPORATION, Tokyo (JP)

(72) Inventors: Fumitoshi Oikawa, Tokyo (JP); Koichi Fukaya, Tokyo (JP); Erina Baba, Tokyo (JP); Shuichi Suemasa, Tokyo (JP); Hisajiro Nakano, Tokyo (JP)

(21) Appl. No.: 18/511,727

(22) Filed: Nov. 16, 2023

Related U.S. Application Data
(62) Division of application No. 17/561,268, filed on Dec. 23, 2021.

(30) Foreign Application Priority Data
Dec. 28, 2020 (JP) 2020-218355

(51) Int. Cl. B08B 3/02; B08B 1/04

(52) U.S. Cl. CPC B08B 3/024; B08B 1/04; B08B 2203/0288

(57) ABSTRACT

A substrate cleaning device includes a rotation mechanism that rotates the substrate, a first cleaning solution supply nozzle that discharges a cleaning solution to which ultrasonic vibration is applied to the surface of the substrate, and a swing mechanism that swings the first cleaning solution supply nozzle from a vicinity of a rotation center of the substrate toward an outer peripheral edge of the substrate in a range narrower than a half-surface of the substrate.

### CROSS REFERENCE TO RELATED APPLICATION

This application is a divisional of U.S. patent application Ser. No. 17/561,268 filed on Dec. 23, 2021, which claims priority based on Japanese Patent Application No. 2020-218355 filed on Dec. 28, 2020, the contents of both are incorporated herein by reference.

### BACKGROUND OF THE INVENTION

### Field of the Invention

The present invention relates to a substrate cleaning device and a method of cleaning a substrate.

### Background Art

Japanese Patent No. 4481394 discloses a substrate cleaning device that discharges a cleaning solution to which ultrasonic vibration is applied from a cleaning solution supply nozzle onto the surface of a substrate.

The cleaning solution supply nozzle is integrally formed with an ultrasonic vibrator, and a tip of the nozzle thereof is arranged at a predetermined distance from the outer peripheral edge of the substrate to the outside in the radial direction of the substrate. Since the nozzle diameter of the cleaning solution supply nozzle is larger than the thickness of the substrate, both the front and back surfaces of the substrate can be cleaned at the same time.

In such ultrasonic cleaning, it is known that cavitation, which forms part of the cleaning principle, can cause pits (microscopic hole defects) on the substrate in some cases. Conventionally, even when cavitation occurs and pits are generated, there was substantially no need to consider the adverse effect of cavitation on the performance and yield of semiconductor substrate products. However, with recent semiconductor substrate products having a miniaturized wiring size, there are cases where pits are generated that are relatively large compared to the structure of the miniaturized wiring size, and there have been examples that concern the adverse effect on the performance and yield of the semiconductor substrate products.

In addition, when semiconductor substrate products with the recent miniaturized wiring size are inspected with a defect inspection device appropriate for the miniaturized wiring size, there are cases where residues from the film formation or etching process are attached to an edge of the substrate in a very unstable state. There have been examples in which the flow of ultrasonic cleaning solution from the edge of the substrate to the center of the substrate causes these foreign substances to reattach to and remain on the substrate surface, which is detected as a final surface defect in some cases.

### SUMMARY

The present invention has been made in view of the above circumstances, and provides a substrate cleaning device and a method of cleaning a substrate capable of efficiently removing foreign substances attached to a substrate while reducing the load on the substrate due to ultrasonic cleaning.

A first aspect of the present application is a substrate cleaning device including a rotation mechanism that rotates the substrate, a first cleaning solution supply nozzle that discharges a cleaning solution to which ultrasonic vibration is applied to the surface of the substrate, and a swing mechanism that swings the first cleaning solution supply nozzle from a vicinity of a rotation center of the substrate toward an outer peripheral edge of the substrate in a range narrower than a half-surface of the substrate.

A second aspect of the present application is a substrate cleaning device including a rotation mechanism that rotates the substrate, a first cleaning solution supply nozzle that discharges a cleaning solution to which ultrasonic vibration is applied to the surface of the substrate, a roll cleaning member that cleans the substrate by rotating while contacting the surface of the substrate at a position passing through a rotation center of the substrate, and a swing mechanism that swings the first cleaning solution supply nozzle in a range narrower than a half-surface of the substrate while the roll cleaning member is cleaning the substrate.

According to the third aspect of the present application, in the substrate cleaning device of the above-described first or second aspect, the first cleaning solution supply nozzle may discharge the cleaning solution in a direction away from the rotation center of the substrate.

According to the fourth aspect of the present application, in the substrate cleaning device of any one of the above-described first to third aspects, the cleaning solution may be an alkaline aqueous solution or an anionic surfactant.

According to the fifth aspect of the present application, the substrate cleaning device of any one of the above-described first to fourth aspects may further include a second cleaning solution supply nozzle that is installed at a position away from the swing range of the first cleaning solution supply nozzle and discharges the cleaning solution onto the surface of the substrate.

According to the sixth aspect of the present application, in the substrate cleaning device of any one of the above-described first to fifth aspects, the swing mechanism may perform at least one of a deceleration and a pause of the swing of the first cleaning solution supply nozzle at least at one of the vicinity of the rotation center of the substrate and the outer peripheral edge of the substrate.

According to the seventh aspect of the present application, the substrate cleaning device of any one of the above-described first to sixth aspects may further include a tilting mechanism that performs at least one of the following: tilting the first cleaning solution supply nozzle toward the rotation center of the substrate in the vicinity of a rotation center of the substrate; and tilting the first cleaning solution supply nozzle toward the outer peripheral edge of the substrate in the vicinity of the outer peripheral edge of the substrate.

An eighth aspect of the present application is a method of cleaning a substrate including, rotating the substrate, discharging from the first cleaning solution supply nozzle, a cleaning solution to which ultrasonic vibration is applied to the surface of the substrate, and swinging the first cleaning solution supply nozzle from a vicinity of a rotation center of the substrate toward an outer peripheral edge of the substrate in a range narrower than a half-surface of the substrate.

A ninth aspect of the present application is a method of cleaning a substrate including, rotating the substrate, discharging from the first cleaning solution supply nozzle, a cleaning solution to which ultrasonic vibration is applied to the surface of the substrate, cleaning the substrate by rotating a roll cleaning member placed at a position passing through a rotation center of the substrate while contacting the surface of the substrate, and swinging the first cleaning solution supply nozzle in a range narrower than a half-surface of the substrate while the roll cleaning member is cleaning the substrate.

According to the tenth aspect of the present application, the method of cleaning a substrate of the above-described eighth or ninth aspect may include discharging from the first cleaning solution supply nozzle, the cleaning solution in a direction away from the rotation center of the substrate.

According to the eleventh aspect of the present application, in the method of cleaning a substrate of any one of the above-described eighth to tenth aspects, the cleaning solution may be an alkaline aqueous solution or an anionic surfactant.

According to the twelfth aspect of the present application, in the method of cleaning a substrate of any one of the above-described eighth to eleventh aspects, a second cleaning solution supply nozzle may be installed at a position away from the swing range of the first cleaning solution supply nozzle, and the cleaning solution may be discharged onto the surface of the substrate.

According to the thirteenth aspect of the present application, the method of cleaning a substrate of any one of the above-described eighth to twelfth aspects may include performing at least one of a deceleration and a pause of the swing of the first cleaning solution supply nozzle at least at one of the vicinity of the rotation center of the substrate and at the outer peripheral edge of the substrate.

According to the fourteenth aspect of the present application, the method of cleaning a substrate of any one of the above-described eighth to thirteenth aspects may include performing at least one of the following: tilting the first cleaning solution supply nozzle toward the rotation center of the substrate in the vicinity of a rotation center of the substrate; and tilting the first cleaning solution supply nozzle toward the outer peripheral edge of the substrate in the vicinity of the outer peripheral edge of the substrate.

According to the fifteenth aspect of the present application, the method of cleaning a substrate of the above-described eighth aspect may include primary cleaning the substrate by swinging the first cleaning solution supply nozzle that discharges a cleaning solution to which the ultrasonic vibration is applied, after the primary cleaning, secondary cleaning the substrate by rotating the roll cleaning member arranged at a position passing through a rotation center of the substrate while contacting the surface of the substrate, and after the secondary cleaning, further tertiary cleaning the substrate by swinging the first cleaning solution supply nozzle that discharges the cleaning solution to which ultrasonic vibration is applied.

According to the sixteenth aspect of the present application, the method of cleaning a substrate of the above-described eighth aspect may include, primary cleaning the substrate by rotating the roll cleaning member arranged at a position passing through a rotation center of the substrate while contacting the surface of the substrate, and after the primary cleaning, secondary cleaning the substrate by swinging the first cleaning solution supply nozzle that discharges a cleaning solution to which ultrasonic vibration is applied.

According to one or more aspects of the present invention described above, foreign matter adhered to the substrate can be efficiently removed while reducing the load on the substrate due to ultrasonic cleaning.

### BRIEF DESCRIPTION OF THE DRAWINGS

FIG. 1 is a plan view showing an overall structure of the substrate processing apparatus according to an embodiment.

FIG. 2 is a plan view showing the structure of the substrate cleaning device according to an embodiment.

FIG. 3 is an arrow view of an A-A line of FIG. 2.

FIG. 4 is a plan view showing a state of ultrasonic cleaning in which the swing of the cleaning solution supply nozzle is started from the center position, which is the rotation center of the substrate, as Comparative Example 1.

FIG. 5 is a plan view showing a state of ultrasonic cleaning in which the swing of the cleaning solution supply nozzle is started from the near-center position near the rotation center of the substrate as an Example.

FIG. 6 is a plan view showing a state of ultrasonic cleaning in which the swing of the cleaning solution supply nozzle is started from the near-edge position near the outer peripheral edge of the substrate as Comparative Example 2.

FIG. 7 is a graph comparing the damage number (load) to the substrate W due to ultrasonic cleaning and the particle removal performance (cleaning performance) in Comparative Examples 1 and 2 and the Example.

FIG. 8 is an explanatory diagram of the radial position and the moving velocity of the cleaning solution supply nozzle of the substrate cleaning device according to the modification example of an embodiment.

FIG. 9 is a front view showing a main structure of a substrate cleaning device according to a modification example of an embodiment.

### DESCRIPTION OF THE PREFERRED EMBODIMENTS

Hereinafter, an embodiment of the present invention will be described with reference to the drawings. In the following, as an application example of the substrate cleaning device and the method of cleaning a substrate, a substrate processing apparatus including a polisher for polishing the substrate and a cleaner for cleaning the substrate will be illustrated.

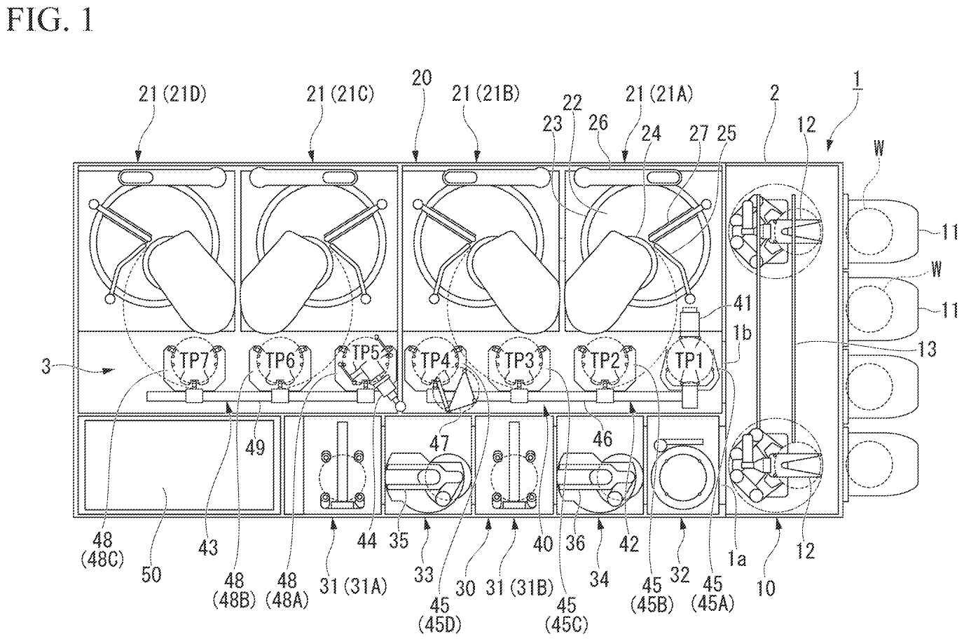

FIG. 1 is a plan view showing an overall structure of the substrate processing apparatus 1 according to an embodiment.

The substrate processing apparatus 1 shown in FIG. 1 is a chemical mechanical polishing (CMP) apparatus that flatly polishes the surface of a substrate W such as a silicon wafer. The substrate processing apparatus 1 includes a rectangular box-shaped housing 2. The housing 2 is formed in a substantially rectangular shape in plan view.

The housing 2 includes a substrate transport path 3 extending in the longitudinal direction in the center thereof. A loader/unloader 10 is disposed at one end portion of the substrate transport path 3 in the longitudinal direction. A polisher 20 is disposed on one end side of the substrate transport path 3 in the width direction (direction orthogonal to the longitudinal direction in plan view), and a cleaner 30 is disposed on the other end side. The substrate transport path 3 is provided with a substrate transporter 40 that transports the substrate W. In addition, the substrate processing apparatus 1 includes a controller (control device) 50 that comprehensively controls the operations of the loader/unloader 10, the polisher 20, the cleaner 30, and the substrate transporter 40.

The loader/unloader 10 includes a front loader 11 that accommodates the substrate W. A plurality of front loaders 11 are provided on the side surface of the housing 2 on one end side in the longitudinal direction. The plurality of front loaders 11 are arranged in the width direction of the housing 2. The front loader 11 includes, for example, an open cassette, a Standard Manufacturing Interface (SMIF) pod, or a Front Opening Unified Pod (FOUP). The SMIF and the FOUP are airtight containers in which the cassette of the substrate W is housed and covered with a partition wall, and an environment independent of the external space can be maintained.

In addition, the loader/unloader 10 includes two transfer robots 12 that move the board W in and out from the front loader 11, and a traveling mechanism 13 that causes each transfer robot 12 to travel along the alignment of the front loader 11. Each transfer robot 12 includes two hands in the vertical direction, and are used depending on before and after the processing of the substrate W. For example, the upper hand is used when returning the substrate W to the front loader 11, and the lower hand is used when the substrate W before processing is taken out from the front loader 11.

The polisher 20 includes a plurality of substrate polishing devices 21 (21A, 21B, 21C, and 21D) that polish (flatten) the substrate W. The plurality of substrate polishing devices 21 are arranged in the longitudinal direction of the substrate transport path 3. The substrate polishing device 21 includes a polishing table 23 that rotates a polishing pad 22 having a polishing surface, a top ring 24 that holds the substrate W and polishes the substrate W while pressing the polishing pad 22 on the polishing table 23, a polishing solution supply nozzle 25 that supplies a polishing solution or a dressing solution (for example, pure water) to the polishing pad 22, a dresser 26 that dresses the polished surface of the polishing pad 22, and an atomizer 27 that atomizes and sprays liquid (for example, pure water) or a mixed fluid of liquid (for example, pure water) and gas (for example, nitrogen gas) onto the polished surface.

The substrate polishing device 21 presses the substrate W against the polishing pad 22 by the top ring 24 while supplying the polishing fluid from the polishing solution supply nozzle 25 onto the polishing pad 22, and further polishes the substrate W to flatten the surface thereof by moving the top ring 24 and the polishing table 23 relative to each other. Hard particles such as diamond particles or ceramic particles are fixed to a rotator of a tip that contacts the polishing pad 22, and the rotator swings while rotating; thereby, the dresser 26 uniformly dresses the entire polishing surface of the polishing pad 22 to form a flat polishing surface. The atomizer 27 accomplishes the purification of the polishing surface and the refinement work of the polishing surface by dresser 26, which is a mechanical contact, i.e., the regeneration of the polishing surface, by washing away the polishing debris, abrasive particles, and the like remaining on the polishing surface of polishing pad 22 with a high-pressure fluid.

The cleaner 30 includes a plurality of substrate cleaning devices 31 (31A and 31B) that clean substrates W, and substrate drying devices 32 that dry cleaned substrates W. The plurality of substrate cleaning devices 31 and substrate drying devices 32 are arranged in the longitudinal direction of the substrate transfer path 3. A first transfer chamber 33 is provided between the substrate cleaning device 31A and the substrate cleaning device 31B. In the first transfer chamber 33, a transfer robot 35 is provided that transfers a substrate W among the substrate transfer portion 40, the substrate cleaning device 31A, and the substrate cleaning device 31B. In addition, a second transfer chamber 34 is provided between the substrate cleaning device 31B and the substrate drying device 32. In the second transfer chamber 34, a transfer robot 36 is provided that transfers the substrate W between the substrate cleaning device 31B and the substrate drying device 32.

The substrate cleaning device 31 includes a cleaning module described later and cleans the substrate W. The substrate cleaning device 31A and the substrate cleaning device 31B may be the same type or different types of cleaning modules. The substrate drying device 32 includes, for example, a drying module that performs Rotagoni drying (IPA (Iso-Propyl Alcohol) drying). After drying, the shutter 1a provided on the partition wall between the substrate drying device 32 and the loader/unloader 10 is opened, and the substrate W is taken out from the substrate drying device 32 by the transfer robot 12.

The substrate transfer portion 40 includes a lifter 41, a first linear transporter 42, a second linear transporter 43, and a swing transporter 44. The substrate transfer path 3 has a first transfer position TP1, a second transfer position TP2, a third transfer position TP3, a fourth transfer position TP4, a fifth transfer position TP5, a sixth transfer position TP6, and a seventh transfer position TP7 in order from the loader/unloader 10 side.

The lifter 41 is a mechanism that transports the substrate W up and down at the first transfer position TP1. The lifter 41 receives the substrate W from the transfer robot 12 of the loader/unloader 10 at the first transfer position TP1. The lifter 41 also receives the substrate W received from the transfer robot 12 and passes it to the first linear transporter 42. A shutter 1b is provided on the bulkhead between the first transfer position TP1 and the loader/unloader 10, and when the substrate W is transferred, the shutter 1b is opened and the substrate W is passed from the transfer robot 12 to the lifter 41.

The first linear transporter 42 is a mechanism for transporting the substrate W between the first transport position TP1, the second transport position TP2, the third transport position TP3, and the fourth transport position TP4. The first linear transporter 42 includes a plurality of transfer hands 45 (45A, 45B, 45C, and 45D) and a linear guide mechanism 46 that moves each transfer hand 45 at a plurality of heights in the horizontal direction. The transfer hand 45A moves between the first transport position TP1 and the fourth transport position TP4 by the linear guide mechanism 46. The transfer hand 45A is a pass hand that receives the substrate W from the lifter 41 and delivers the received substrate W to the second linear transporter 43.

The transfer hand 45B moves between the first transport position TP1 and the second transport position TP2 by the linear guide mechanism 46. The transfer hand 45B receives the substrate W from the lifter 41 at the first transport position TP1 and delivers the substrate W to the substrate polishing device 21A at the second transport position TP2. The transfer hand 45B is provided with an elevating and descending drive portion, and rises when the substrate W is delivered to the top ring 24 of the substrate polishing device 21A and descends after the substrate W is delivered to the top ring 24. The transfer hand 45C and the transfer hand 45D are also provided with a similar elevating and descending drive portion.

The transfer hand 45C moves between the first transfer position TP1 and the third transfer position TP3 by the linear guide mechanism 46. The transfer hand 45C receives the substrate W from the lifter 41 at the first transfer position TP1 and passes the substrate W to the substrate polishing device 21B at the third transfer position TP3. The transfer hand 45C also functions as an access hand that receives the substrate W from the top ring 24 of the substrate polishing device 21A at the second transfer position TP2 and passes the substrate W to the substrate polishing device 21B at the third transfer position TP3.

The transfer hand 45D moves between the second transfer position TP2 and the fourth transfer position TP4 by the linear guide mechanism 46. The transfer hand 45D functions as an access hand that receives the substrate W from the top ring 24 of the substrate polishing device 21A or the substrate polishing device 21B at the second transfer position TP2 or the third transfer position TP3 and passes the substrate W to the swing transporter 44 at the fourth transfer position TP4.

The swing transporter 44 has a hand that can move between the fourth transfer position TP4 and the fifth transfer position TP5, and passes the substrate W from the first linear transporter 42 to the second linear transporter 43. The swing transporter 44 also passes the substrate W that has been polished in the polisher 20 to the cleaner 30. A temporary storage platform 47 for the substrate W is provided on the side of the swing transporter 44. The swing transporter 44 turns the substrate W received at the fourth transfer position TP4 or the fifth transfer position TP5 upside down and places it on the temporary placement table 47. The substrate W placed on the temporary stand 47 is transferred to the first transfer chamber 33 by the transfer robot 35 of the cleaner 30.

The second linear transporter 43 is a mechanism for transferring a substrate W between the fifth, sixth, and seventh transfer positions TP5, TP6, and TP7. The second linear transporter 43 has a plurality of transfer hands 48 (48A, 48B, and 48C) and a linear guide mechanism 49 that moves each transfer hand 45 horizontally at a plurality of heights. The transfer hand 48A moves between the fifth transfer position TP5 and the sixth transfer position TP6 by the linear guide mechanism 49. The transfer hand 45A functions as an access hand that receives the substrate W from the swing transporter 44 and delivers the received substrate W to the substrate polishing device 21C.

The transfer hand 48B moves between the sixth transfer position TP6 and the seventh transfer position TP7. The transfer hand 48B functions as an access hand that receives the substrate W from the substrate polishing device 21C and delivers the received substrate W to the substrate polishing device 21D. The transfer hand 48C moves between the seventh transfer position TP7 and the fifth transfer position TP5. The transfer hand 48C functions as an access hand that receives the substrate W from the top ring 24 of the substrate polishing device 21C or the substrate polishing device 21D at the sixth transfer position TP6 or the seventh transfer position TP7 and passes the substrate W to the swing transporter 44 at the fifth transfer position TP5. Although the description is omitted, the operation of the transfer hand 48 when receiving and passing the substrate W is the same as the operation of the first linear transporter 42 described above.

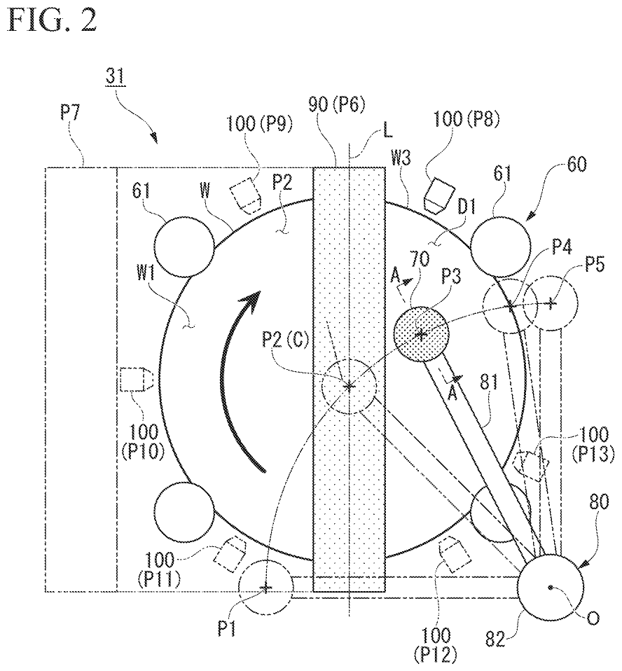

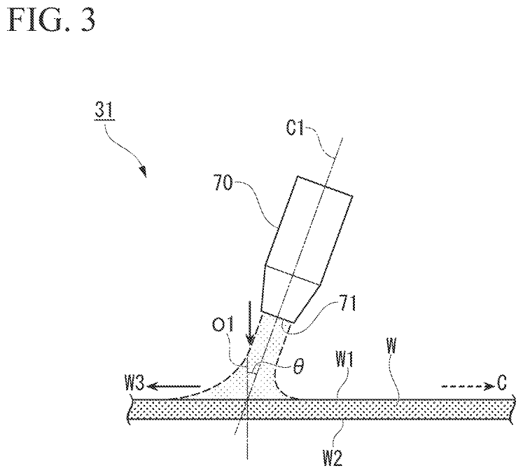

FIG. 2 is a plan view of a substrate cleaning device 31 according to an embodiment. FIG. 3 is an arrow view A-A of FIG. 2.

The substrate cleaning device 31 shown in FIG. 2 has a rotation mechanism 60, a cleaning solution supply nozzle 70, a swing mechanism 80, a roll cleaning member 90, and a second cleaning solution supply nozzle 100.

The rotation mechanism 60 has a plurality of holding rollers 61 that hold the outer peripheral edge W3 of the substrate W and rotate around an axis extending in the vertical direction. The plurality of holding rollers 61 are connected to an electric drive portion such as a motor to rotate horizontally.

The cleaning solution supply nozzle 70 includes an ultrasonic transducer, not shown in the drawings, and discharges a cleaning solution to which ultrasonic vibration is applied to the surface W1 of the substrate W. The vibration frequency of the ultrasonic vibration applied to the cleaning solution is preferably 900 kHz to 5 MHz. The flow amount of the cleaning solution discharged from the cleaning solution supply nozzle 70 depends on the nozzle diameter of the cleaning solution supply nozzle 70; however, it should be from several hundred cc/min to several liters/min. The cleaning solution supply nozzle 70 can also be provided on the backside W2 of the substrate W, and the cleaning solution can be discharged on the backside W2 of the substrate W.

Pure water is used as the cleaning solution, acid or alkaline aqueous solutions such as hydrochloric acid, ammonia, hydrofluoric acid, hydrogen peroxide water, ozone water, electrolytic ionized water (acidic water, alkaline water) as the chemical cleaning chemicals, chemical solutions with oxidizing or reducing power, or cationic, anionic or nonionic surfactants. An alkaline aqueous solution with a pH of 7 or more or an anionic surfactant is particular desirable. The cleaning solution may also be nitrogen-dissolved water with a dissolved nitrogen concentration in the range of 8-16 ppm.

The pivoting mechanism 80 has an arm body 81 and a pivoting axis 82. The arm body 81 has a long shape in plan view and extends horizontally from the pivot axis 82 in the radial direction of the central axis O of the pivot axis 82. At the tip of the arm body 81, the above-mentioned cleaning fluid supply nozzle 70 is supported.

The pivoting shaft 82 is formed in the shape of a cylinder and is connected to an electric drive portion such as a motor to rotate around the central axis line 0 extending in the vertical direction. This causes the arm body 62 to pivot (rotate horizontally) around the central axis line 0.

The cleaning solution supply nozzle 70 can be moved to the evacuation position P1, the center position P2, the near-center position P3, the edge position P4, and the opposite evacuation position P5 by pivoting around the central axis O. The evacuation positions P1 and P5 are the positions that are evacuated from the surface W1 of the substrate W. That is, the cleaning solution supply nozzles 70 located at the evacuation positions P1 and P5 are spaced radially outward from the outer peripheral edge W3 of the substrate W by a predetermined distance.

The center position P2 is the position directly above the rotation center C of the substrate W. The near-center position P3 is a position near the rotation center C of the substrate W, away from the rotation center C of the substrate W. The edge position P4 is the position directly above the outer peripheral edge W3 of the substrate W. In other words, the cleaning solution supply nozzles 70 located at the center position P2, near-center position P3, and edge position P4 overlap with at least a portion of the surface W1 of the substrate W in plan view.

The roll cleaning member 90 cleans the substrate W by rotating in contact with the surface W1 of the substrate W at the cleaning position P6 passing through the rotation center C of the substrate W. The roll cleaning member 90 is a cylindrical sponge body, and is formed of, for example, a PVA (polyvinyl alcohol) sponge or a urethane sponge. The roll cleaning member 90 may be a brush body having brush bristles on the peripheral surface.

The roll cleaning member 90 is pivotally supported by a holder (not shown) and rotates around an axis L extending in the horizontal direction. The holder is made of, for example, PVC (polyvinyl chloride) or PEEK (polyetheretherketone). The holder is supported by an arm (not shown) and is connected to an electric drive portion such as a motor. The roll cleaning member 90 is movable between the cleaning position P6 described above and the retracting position P7 retracted from the surface W1 of the substrate W by an arm (not shown).

The second cleaning solution supply nozzle 100 is installed at a position away from the swing range of the cleaning solution supply nozzle 70, and discharges the cleaning solution (without applying ultrasonic vibration) from diagonally above the surface W1 of the substrate W. The cleaning solution discharged from the second cleaning solution supply nozzle 100 is desirably more expensive than the cleaning solution discharged from the cleaning solution supply nozzle 70 described above, for example, which obtains a cleaning effect by utilizing the effect of zeta potential control. Is desirable. This is because the cleaning solution supply nozzle 70 needs to set a relatively high minimum flow amount of the cleaning solution in order to prevent the ultrasonic vibrator from being heated in the air due to its structure.

During ultrasonic cleaning by the cleaning solution supply nozzle 70, the swing mechanism 80 swings the cleaning solution supply nozzle 70 from the vicinity of the rotation center C of the substrate W to the outer peripheral edge W3 of the substrate W within a narrower range than the half-surface D1 of the substrate W. The half-surface D1 of the substrate W is one side of the half-surfaces D1 and D2 that bisect the surface W1 of the substrate W in plan view with the axis L of the roll cleaning member 90 described above passing through the rotation center C of the substrate W as the boundary line.

In particular, on the half-surface D1 of the substrate W, the pivoting mechanism 80 pivots the cleaning solution supply nozzle 70 between the near-center position P3 and the edge position P4, which is the outer peripheral edge W3 of the substrate W closest to the near-center position P3. The distance from the near-center position P3 to the edge position P4 is smaller than the radius of the substrate W. The near-center position P3 is a position where the cleaning solution supply nozzle 70 does not interfere with the roll cleaning member 90 located at the cleaning position P6, and simultaneous cleaning with the roll cleaning member 90 is possible.

The cleaning solution supply nozzle 70 is inclined to discharge the cleaning solution in the direction away from the rotation center C of the substrate W (toward the outer peripheral edge W3 of the substrate W) in the swing range from the near-center position P3 to the edge position P4 described above (see FIG. 3). As shown in FIG. 3, the central axis Cl of the outlet 71 at the tip of the cleaning solution supply nozzle 70 is inclined at an angle θ to the vertical axis O1 (parallel to the central axis O) relative to the surface W1 of the substrate W. The angle θ should be set in the range of greater than 0° and less than 30°.

Returning to FIG. 2, the second cleaning solution supply nozzle 100 is installed at the first supply position P8, which is upstream of the substrate W in the direction of rotation of the substrate W from the swing range of the cleaning solution supply nozzle 70 in the half-plane D1 of the substrate W on which the cleaning solution supply nozzle 70 swings. This makes it easier for the cleaning fluid discharged from the second cleaning fluid supply nozzle 100 to be mixed with the cleaning fluid discharged from the cleaning fluid supply nozzle 70, thereby achieving a higher cleaning effect.

The second cleaning solution supply nozzle 100 can be installed at a second supply position P9, a third supply position P10, a fourth supply position P11, a fifth supply position P12, or a sixth supply position P13 on the half-surface D2 of the substrate W where the cleaning solution supply nozzle 70 does not swing. However, considering the scattering of the cleaning solution due to the centrifugal force due to the rotation of the substrate W, the second cleaning solution supply nozzle 100 can be installed preferably at the third supply position P10 rather than at the fourth supply position P11, more preferably at the second supply position P9 rather than the third supply position P10, and most preferably at the first supply position P8 on the half-surface D1 of the substrate W described above. The second cleaning solution supply nozzle 100 may be arranged at the fifth supply position P12 and the sixth supply position P13 located on the half-surface D1 of the substrate W, which is the same as the first supply position P8.

Subsequently, the operation (method of cleaning the substrate) of the substrate cleaning device 31 having the structure described above will be described.

First, ultrasonic cleaning by only swinging of the cleaning solution supply nozzle 70 alone will be described. In other words, in the following explanation, the roll cleaning member 90 is assumed to be in the evacuated position P7.

In the ultrasonic cleaning, the holding roller 61 of the rotation mechanism 60 holds the outer peripheral edge W3 of the substrate W, and the substrate W is rotated horizontally.

In the above-described state, the cleaning solution supply nozzle 70 discharges a cleaning solution to the surface W1 of the substrate W to which ultrasonic vibration is applied. The swing mechanism 80 swings the cleaning solution supply nozzle 70 between the near-center position P3 near the rotation center C of the substrate W and the edge position P4 directly above the outer peripheral edge W3 of the substrate W. In such a manner, the cleaning solution supply nozzle 70 is swung on the substrate W. This makes it more difficult for foreign matter, such as residue from film formation or etching attached to the outer peripheral edge W3 of the substrate W to flow toward the rotation center C of the substrate W by the cleaning solution than when the cleaning solution supply nozzle 70 is placed outside the substrate W in the radial direction. Therefore, the reattachment of foreign matter to the surface W1 of the substrate W can be prevented.

In addition, the swing between the near-center position P3 and the edge position P4 becomes the swing within a narrower range than the half-surface D1 of the substrate W, and the stroke is smaller than the radius of the substrate W. Therefore, it is difficult for the cleaning solution to be discharged overlapping some areas of the rotating substrate W. Therefore, the load on the substrate W (generation of pits (i.e., fine hole defects)) caused by cavitation, which is part of the cleaning principle of ultrasonic cleaning, can be reduced.

In other words, the cleaning solution to which ultrasonic vibration is applied is discharged to a certain extent (spread) to the surface W1 of the substrate W. The cleaning solution discharged beyond the rotation center C of the substrate W causes duplicate cleaning of the area subjected to discharge per rotation of the substrate W, which accumulates load. Therefore, as described above, by starting the swing of the cleaning solution supply nozzle 70 from the near-center position P3 in the vicinity of the rotation center C of the substrate W, rather than from the rotation center C of the substrate W, low-load ultrasonic cleaning (ultrasonic cleaning in which there is almost no overlapping of the area to be discharged by the cleaning solution) is possible, taking into account the spread of the cleaning solution.

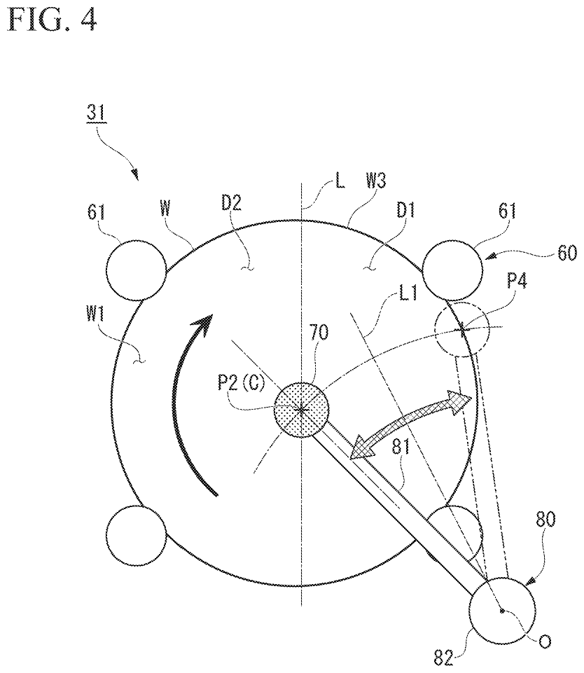

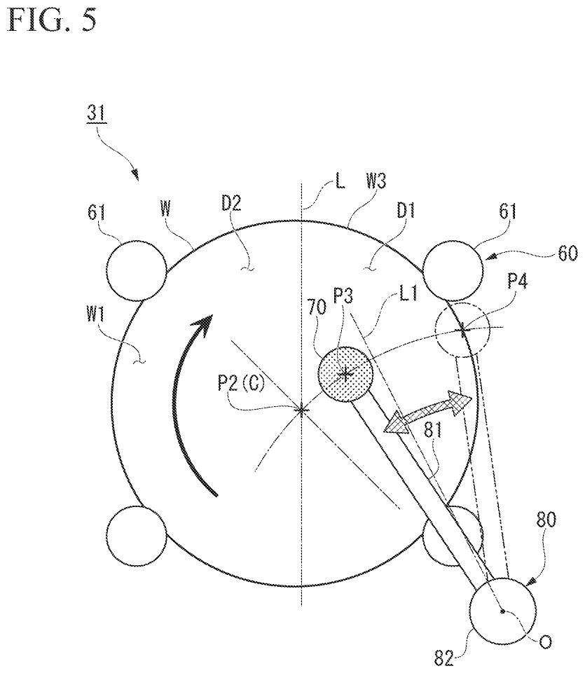

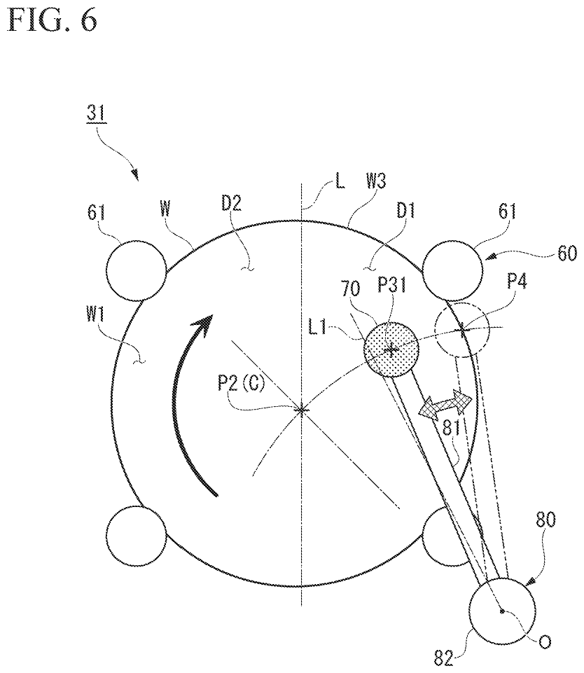

FIG. 4 is a plan view showing a state of ultrasonic cleaning in which the swing of the cleaning solution supply nozzle 70 is started from the center position P2, which is the rotation center C of the substrate W, as Comparative Example 1. FIG. 5 is a plan view showing a state of ultrasonic cleaning in which the swing of the cleaning solution supply nozzle 70 is started from the near-center position P3 near the rotation center C of the substrate W as an example. FIG. 6 is a plan view showing a state of ultrasonic cleaning in which the cleaning solution supply nozzle 70 is started to swing from the near-edge position P31 near the outer peripheral end W3 of the substrate W as Comparative Example 2.

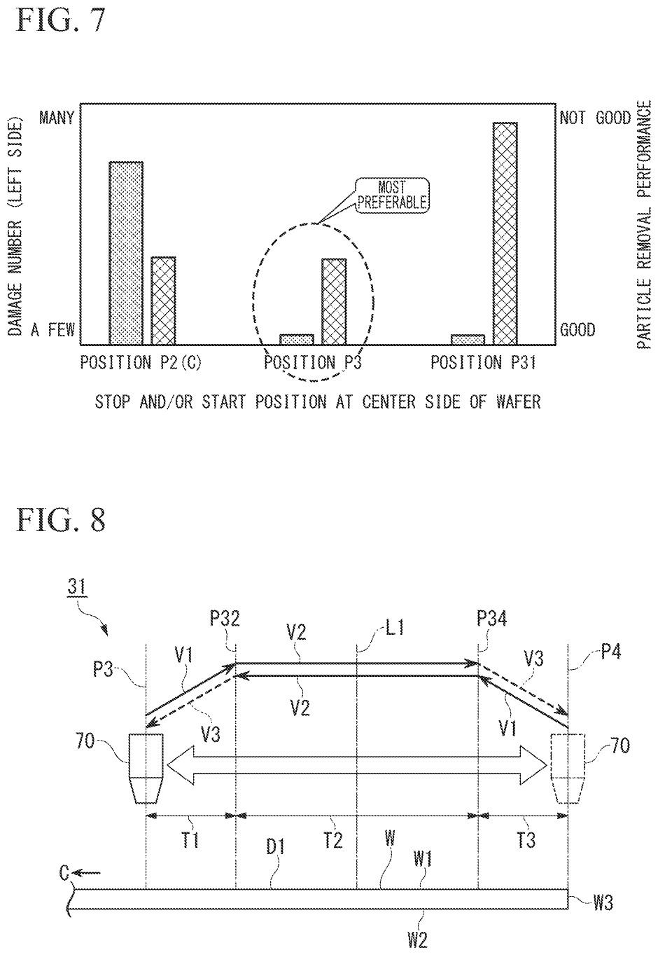

FIG. 7 is a graph comparing the damage number (load) to the substrate W due to ultrasonic cleaning and the particle removal performance (cleaning performance) in Comparative Examples 1 and 2 and Examples.

Note that, in FIGS. 5 and 6, as a guide, the central axis O of the swing shaft 82 and the reference line L1 passing through half of the swing stroke from the center position P2 to the edge position P4 are shown.

The near-center position P3 is the position of the swing stroke from the center position P2 to the edge position P4, which is closer to the center position P2 than ⅔ from the center position P2 side. In particular, when the radius of the substrate W is 150 mm and the nozzle diameter of the cleaning solution supply nozzle 70 is 6 mm, the near-center position P3 of the Example is set to be located 75 mm away from the center position P2, which is the rotation center C of the substrate W.

The near-edge position P31 is the position of the swing stroke from the center position P2 to the edge position P4, which is closer to the edge position P4 than ⅔ from the center position P2 side. In particular, the near-edge position P31 of the comparative example is set at a position 120 mm away from the center position P2, which is the rotation center C of the substrate W. The near-edge position P31 is set at a position 30 mm away from the edge position P4 of the substrate W.

As shown in FIG. 7, comparing the damage number (load) to the substrate W, it can be seen that ultrasonic cleaning in which the swing of the cleaning solution supply nozzle 70 starts from the near-center position P3 or the near-edge position P31 is preferable. In addition, when these two types of ultrasonic cleaning are compared in terms of particle removal performance (cleaning performance), the ultrasonic cleaning in which the swing of the cleaning solution supply nozzle 70 starts from the near-center position P3 is found to be preferable. Therefore, ultrasonic cleaning in which the swing of the cleaning solution supply nozzle 70 is started from the near-center position P3 is most preferable.

When the radius of the substrate W is 150 mm and the nozzle diameter of the cleaning solution supply nozzle 70 is 6 mm, the near-center position P3 should be at least 50 mm away from the center position P2, the rotation center C of the substrate W, from the viewpoint of damage. On the other hand, if it is too far from the center position P2, particle cleaning performance will be degraded, so it is preferable that it not be more than 100 mm away from the center position P2, which is the rotation center C of the substrate W. In other words, the near-center position P3 should be set within the range of 50 mm or more and 100 mm or less from the center position P2.

In such a manner, the above-described embodiment has a rotation mechanism 60 that rotates the substrate W, a cleaning solution supply nozzle 70 that discharges a cleaning solution to which ultrasonic vibration is applied on the surface W1 of the substrate W, and a swing mechanism 80 that swings the cleaning solution supply nozzle 70 from the vicinity of the rotation center C of the substrate W to the outer peripheral edge W3 of the substrate W within a range narrower than the half-surface D1 of the substrate W. By employing such a structure, foreign matter attached to the substrate W can be efficiently removed while reducing the load on the substrate W by ultrasonic cleaning.

In addition, since the swing of the cleaning solution supply nozzle 70 is performed within a narrower range than the half-surface D1 of the substrate W, when the substrate W is being cleaned by rotating the roll cleaning member 90 placed at the cleaning position P6 through the rotation center C of the substrate W in contact with the surface W1 of the substrate W, ultrasonic cleaning due to the swing of the cleaning solution supply nozzle 70 can be performed. In other words, by having the swing mechanism 80 swing the cleaning solution supply nozzle 70 within a narrower range than the half-surface D1 of the substrate W while the roll cleaning member 90 is cleaning the substrate W, scrubbing cleaning of the roll cleaning member 90 and ultrasonic cleaning by swinging the cleaning solution supply nozzle 70 can be performed simultaneously.

According to the above-described structure, since different cleaning methods are performed at a single location, there is no need to add the number of substrate cleaning devices 31 shown in FIG. 1. Furthermore, the addition of transfer robots 35 and 36 is unnecessary, which prevents the floor space of the device from increasing or the device from becoming larger, and prevents the cost of the device and the cost of the device from becoming more expensive. In addition, ultrasonic waves can propagate and clean areas that cannot be sufficiently deformed to be contacted even by the pressing of the roll cleaning member 90, such as concave areas where product patterns are engraved and inside fine seams. The substrate cleaning device 31 with such high cleaning performance should be installed in the first stage cleaning chamber where the contamination level is the highest.

The scrubbing cleaning of the roll cleaning member 90 and the ultrasonic cleaning by swinging the cleaning solution supply nozzle 70 may be performed separately. For example, the roll cleaning member 90 placed at a position through the rotation center C of the substrate W is rotated in contact with the surface W1 of the substrate W. This may perform primary cleaning of the substrate W. After the primary cleaning, the substrate W may be cleaned secondarily by swinging the cleaning solution supply nozzle 70 that discharges the cleaning solution to which ultrasonic vibration is applied.

As described above, the substrate W is roughly cleaned by the scrubbing cleaning of the roll cleaning member 90 in the primary cleaning, and then fine foreign matter is washed away by the cleaning solution with ultrasonic vibration applied in the secondary cleaning. This reduces back contamination on the substrate W after scrubbing, reduces the contamination load on the next cleaning stage, and improves the final cleaning performance after all the cleaning stages.

In addition, for example, primary cleaning of the substrate W is performed by swinging the cleaning solution supply nozzle 70 that discharges the cleaning solution to which ultrasonic vibration is applied, and after the primary cleaning, secondary cleaning of the substrate W is performed by rotating the roll cleaning member 90 arranged at a position passing through the rotation center C of the substrate W while contacting the surface W1 of the substrate W, and after the secondary cleaning, tertiary cleaning of the substrate W may be further performed by swinging the cleaning solution supply nozzle 70 that discharges the cleaning solution to which ultrasonic vibration is applied.

In such a manner, before scrubbing cleaning by the roll cleaning member 90 (secondary cleaning in this case), a process of ultrasonic cleaning by supplying a cleaning solution to which ultrasonic vibration is applied (primary cleaning in this case) is added. This reduces the amount of contamination on the substrate W prior to scrubbing cleaning, reduces the contamination load on the roll cleaning member 90, and extends the life of the roll cleaning member 90.

In the present embodiment, as shown in FIG. 3, the cleaning solution supply nozzle 70 discharges the cleaning solution in a direction away from the rotation center C of the substrate W, so that the cleaning solution that has cleaned the outer peripheral edge W3 of the substrate W can be prevented from returning to the rotation center C side of the surface W1 of the substrate W. In particular, the issue of foreign matter removed from the outer peripheral edge W3 of the substrate W reattaching and remaining on the surface W1 of the substrate W and becoming a final defect can be suppressed.

The cleaning solution discharged from the cleaning solution supply nozzle 70 should be an alkaline aqueous solution or an anionic surfactant. The cleaning solution is an alkaline aqueous solution or an anionic surfactant, which controls the zeta potential of the surface of foreign matter in the cleaning solution, weakens the adhesion between the substrate W and the foreign matter, makes it easier to be removed and harder to be reattached, and improves the particle removal performance.

In the present embodiment, as shown in FIG. 2, a second cleaning solution supply nozzle 100 is installed at a position remote from the swinging range of the cleaning solution supply nozzle 70 and discharges a cleaning solution onto the surface W1 of the substrate W. By providing such a second cleaning solution supply nozzle 100, an expensive cleaning solution can be supplied from the second cleaning solution supply nozzle 100, and the cleaning solution of the cleaning solution supply nozzle 70, which includes the function of applying ultrasonic waves, can be relatively inexpensive. Therefore, even if the minimum flow amount needs to be set relatively high to prevent the ultrasonic transducer from burning dry, the running cost can be kept low.

Although preferred embodiments of the present invention have been described and explained above, it should be understood that these are illustrative of the invention and should not be considered as limiting. Additions, omissions, substitutions, and other changes can be made without departing from the scope of the present invention. Therefore, the present invention should not be considered limited by the foregoing description; however, is limited by the claims.

The above-described example describes a structure and method of efficiently removing foreign matter attached to the substrate W while reducing the load of ultrasonic cleaning on the vicinity of the rotation center C of the substrate W by narrowing the swing stroke of the cleaning solution supply nozzle 70 on the side of the rotation center C of the substrate W; however, this is not limited to the above.

For example, the water landing position of the second cleaning solution supply nozzle 100 on the substrate W is set to be the center position P2 to moderately reduce the influence of the cleaning solution to which ultrasonic waves are added from the cleaning solution supply nozzle 70 on the center position P2. In such a manner, a structure and method are provided that can efficiently remove foreign matter attached to the substrate W while reducing the load on the substrate W by ultrasonic cleaning near the rotation center C of the substrate W.

For example, the water landing position of the second cleaning solution supply nozzle 100 on the substrate W is set to the center position P2, and the second cleaning solution is supplied such that the temperature thereof is higher than room temperature. This maintains a high temperature of the cleaning solution near the rotation center C of the substrate W and suppresses the generation and collapse of bubbles in the solution, which is the mechanism of ultrasonic cleaning (the collapse of bubbles in the solution is caused by the difference between the vapor pressure of the bubbles and the pressure of the surrounding solution, so the vapor pressure is high when the temperature is high, and the collapse of bubbles is suppressed). In such a manner, the ultrasound-added cleaning solution from the cleaning solution supply nozzle 70 is moderately reduced to affect the center position P2, and there is also a structure and method that can efficiently remove foreign matter attached to the substrate W while reducing the load on the substrate W by ultrasonic cleaning near the rotation center C of the substrate W.

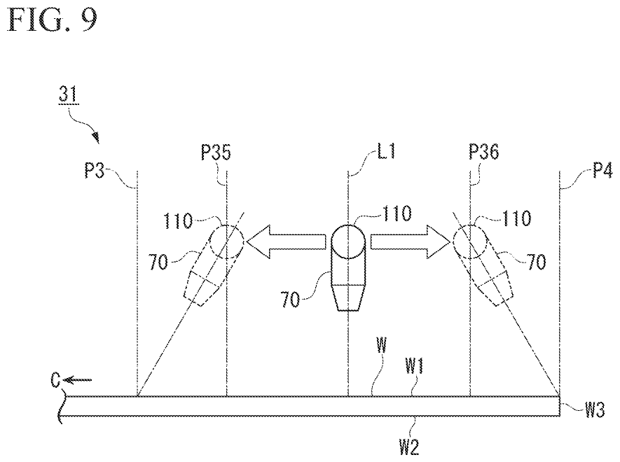

Furthermore, for example, the modification examples shown in FIGS. 8 and 9 can be adopted.

FIG. 8 is an explanatory diagram of the radial position and moving velocity of the cleaning solution supply nozzle of the substrate cleaning device 31 in a modification example of an embodiment.

As in the substrate cleaning device 31 shown in FIG. 8, the swing mechanism 80 (not shown in FIG. 8) may decelerate and pause the swing of the cleaning solution supply nozzle 70 at least at one of the vicinity of the rotation center C of the substrate W and at the outer peripheral edge W3 of the substrate W. In FIG. 8, the reference symbol V1 indicates acceleration, the reference symbol V2 indicates constant velocity, and the reference symbol V3 indicates deceleration.

According to the above structure, the relative velocity is low in scrubbing cleaning by the roll cleaning member 90. This increases the cleaning time in the vicinity of the rotation center C of the substrate W, where contamination is easily concentrated, and in the vicinity of the outer peripheral edge W3 of the substrate W, where the cleaning time per portion time is short due to the large amount of contamination and the long rotation circumference of the substrate W. Therefore, the entire surface W1 of the substrate W can be cleaned uniformly.

To increase the cleaning time in the vicinity of the rotation center C of the substrate W and in the vicinity of the outer peripheral edge W3 of the substrate W, the switching position P32 at which the swing of the cleaning solution supply nozzle 70 is switched from the constant velocity V2 to the deceleration V3 may be set closer to the reference line L1 than halfway between the reference line L1 and the near-center position P3. The switching position P34, which switches the swing of the cleaning fluid supply nozzle 70 from constant velocity V2 to deceleration V3, may be set closer to the reference line L1 than halfway between the reference line L1 and the edge position P4.

The time T1 and T3 for deceleration V3 (or pause) may be set to be longer (e.g., more than twice as long) than the time T2 for swinging at constant velocity V2.

FIG. 9 is a front view showing a main structure of a substrate cleaning device 31 according to a modification example of an embodiment.

As shown in FIG. 9, the substrate cleaning device 31 may be provided with a tilt mechanism 110 that performs at least one of the following: tilting the cleaning solution supply nozzle 70 toward the rotation center C of the substrate W in the vicinity of the rotation center C of the substrate W, and tilting the cleaning solution supply nozzle 70 toward the outer peripheral edge W3 of the substrate W in the vicinity of the outer peripheral edge W3 of the substrate W. The tilt mechanism 110 may include an electric drive such as a motor supported by the pivoting shaft 82 shown in FIG. 2, and is configured to rotate the arm body 81 around an axis extending in the longitudinal direction thereof from outside the radial direction of the substrate W. This can prevent contamination of the substrate W due to the increase of moving portions in the cleaning solution supply nozzle 70.

According to the above-described structure, at the first inclination position P35 before the near-center position P3 on the rotation center C side of the substrate W, the cleaning solution supply nozzle 70 can be further inclined toward the rotation center C side to bring the water landing position on the substrate W closer to the rotation center C side of the substrate W. Also, according to the above structure, at the second inclination position P36 before the edge position P4 on the outer peripheral edge W3 side of the substrate W, the cleaning solution supply nozzle 70 can be further inclined toward the outer peripheral edge W3 side to bring the water landing position on the substrate W closer to the outer peripheral edge W3 side of the substrate W. This makes it possible to sufficiently clean the surface W1 of the substrate W with the cleaning solution supplied from the cleaning solution supply nozzle 70 while shortening the swing range of the cleaning solution supply nozzle 70.

In order to prevent foreign matter attached to the outer peripheral edge W3 of the substrate W from reattaching to the surface W1 of the substrate W, the absolute value of the inclination angle of the cleaning solution supply nozzle 70 at the second inclination position P36 may be larger than the absolute value of the inclination angle of the cleaning solution supply nozzle 70 at the first inclination position P35. This allows the cleaning solution to be discharged in a direction farther away from the rotation center C of the substrate W, thereby preventing the cleaning solution that has cleaned the outer peripheral edge W3 of the substrate W from returning to the rotation center C side of the surface W1 of the substrate W more reliably.

What is claimed is:

1. A method of cleaning a substrate comprising:
rotating the substrate;
discharging from the first cleaning solution supply nozzle, a cleaning solution to which ultrasonic vibration is applied to the surface of the substrate; and
swinging the first cleaning solution supply nozzle from a vicinity of a rotation center of the substrate toward an outer peripheral edge of the substrate in a range narrower than a half-surface of the substrate.

2. A method of cleaning a substrate comprising:
rotating the substrate;
discharging from the first cleaning solution supply nozzle, a cleaning solution to which ultrasonic vibration is applied to the surface of the substrate;
cleaning the substrate by rotating a roll cleaning member placed at a position passing through a rotation center of the substrate while contacting the surface of the substrate; and
swinging the first cleaning solution supply nozzle in a range narrower than a half-surface of the substrate while the roll cleaning member is cleaning the substrate.

3. The method of cleaning a substrate according to claim 1, comprising discharging from the first cleaning solution supply nozzle, the cleaning solution in a direction away from the center of rotation of the substrate.

4. The method of cleaning a substrate according to claim 1, wherein the cleaning solution is an alkaline aqueous solution or an anionic surfactant.

5. The method of cleaning a substrate according to claim 1, wherein a second cleaning solution supply nozzle is installed at a position away from the swing range of the first cleaning solution supply nozzle, and the cleaning solution is discharged onto the surface of the substrate.

6. The method of cleaning a substrate according to claim 1, comprising performing at least one of a deceleration and a pause of the swing of the first cleaning solution supply nozzle at least one of at the vicinity of the center of rotation of the substrate and at the outer peripheral edge of the substrate.

7. The method of cleaning a substrate according to claim 1, comprising performing at least one of the following: tilting the first cleaning solution supply nozzle toward the center of rotation of the substrate in the vicinity of a rotation center of the substrate; and tilting the first cleaning solution supply nozzle toward the outer peripheral edge of the substrate in the vicinity of the outer peripheral edge of the substrate.

8. The method of cleaning a substrate according to claim 1, comprising:
primary cleaning the substrate by swinging the first cleaning solution supply nozzle that discharges a cleaning solution to which the ultrasonic vibration is applied;
after the primary cleaning, secondary cleaning the substrate by rotating the roll cleaning member arranged at a position passing through a rotation center of the substrate while contacting the surface of the substrate; and
after the secondary cleaning, further tertiary cleaning the substrate by swinging the first cleaning solution supply nozzle that discharges the cleaning solution to which ultrasonic vibration is applied.

9. The method of cleaning a substrate according to claim 1, comprising:
primary cleaning the substrate by rotating the roll cleaning member arranged at a position passing through a rotation center of the substrate while contacting the surface of the substrate; and
after the primary cleaning, secondary cleaning the substrate by swinging the first cleaning solution supply nozzle that discharges a cleaning solution to which ultrasonic vibration is applied.
